(19) United States
(12) Patent Application Publication
(10) Pub. No.: US 2026/0371672 A1
(43) Pub. Date: Nov. 19, 2026

(54) BIPOLAR TRANSISTOR STRUCTURE WITH INTERFACIAL NITRIDE LAYER AND RELATED METHODS

(71) Applicant: GlobalFoundries Singapore Pte. Ltd., Singapore (SG)

(72) Inventors: Johnson Kasim, Singapore (SG); Jingyan Huang, Singapore (SG); Kangjian Cheng, Singapore (SG); Ming Chou Lim, Johor (MY); Seow Wei Lai, Singapore (SG); Kien Seen Daniel Chong, Singapore (SG)

(21) Appl. No.: 19/211,395

(22) Filed: May 19, 2025

(51) Int. Cl. H10D 62/17; H10D 10/01; H10D 10/80; H10D 62/13; H10D 62/824

(52) U.S. Cl. CPC H10D 62/177; H10D 10/021; H10D 10/821; H10D 62/136; H10D 62/824

(57) ABSTRACT

The disclosure provides bipolar transistor structures with an interfacial nitride layer and related methods to form the same. A structure according to the disclosure includes an interfacial nitride layer vertically between a base material having a first conductivity type, and an emitter material with a second conductivity type.

### BACKGROUND

The present disclosure relates to bipolar transistor structures and methods to form such structures.

Present technology is at the atomic level scaling of certain micro-devices such as logic gates, bipolar transistors, field effect transistors (FETs), and capacitors. Circuit chips with millions of such devices are common. The structure of a bipolar transistor defines several of its properties during operation. Bipolar transistors typically include multiple materials within their base terminal, i.e., the terminal for controlling current flow between the emitter and collector terminals of the bipolar transistor. A base terminal includes a relatively high conductivity extrinsic base having a terminal thereto, and a relatively low conductivity intrinsic base connected to the extrinsic base and located between the emitter and collector. In some cases, dopant diffusion from the emitter and collector into the intrinsic base may occur over time, negatively affecting performance.

### SUMMARY

The illustrative aspects of the present disclosure are designed to solve the problems herein described and/or other problems not discussed.

Embodiments of the disclosure provide a structure including an interfacial nitride layer vertically between a base material having a first conductivity type, and an emitter material with a second conductivity type.

Other embodiments of the disclosure provide a vertical bipolar transistor structure comprising: a base material on a collector material, wherein the base material has a first conductivity type and the collector material has a second conductivity type opposite the first conductivity type, and the base material includes: an intrinsic base on the collector material, and an extrinsic base coupled to the intrinsic base, wherein the extrinsic base has a higher dopant concentration than the intrinsic base; an interfacial nitride layer on the intrinsic base of the base material; and an emitter material on the interfacial nitride layer and having the second conductivity type, wherein the interfacial nitride layer is vertically interposed between the base material and the emitter material.

Additional embodiments of the disclosure provide a method including: forming a base material having a first conductivity type; forming an interfacial nitride layer on the base material; and forming an emitter material on the interfacial nitride layer, the emitter material having a second conductivity type.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 depicts a cross-sectional view of a structure according to embodiments of the disclosure;

FIG. 2-7 depict processes in methods to form a structure according to embodiments of the disclosure;

FIG. 8 depicts a cross-sectional view of a structure according to embodiments of the disclosure;

FIG. 9 depicts a cross-sectional view of another structure according to further embodiments of the disclosure.

It is noted that the drawings of the disclosure are not necessarily to scale. The drawings are intended to depict only typical aspects of the disclosure and therefore should not be considered as limiting the scope of the disclosure. In the drawings, like numbering represents like elements between the drawings.

### DETAILED DESCRIPTION

In the following description, reference is made to the accompanying drawings that form a part thereof, and in which are shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The disclosure provides bipolar transistor structures with an interfacial nitride layer and related methods to form the same. A structure, according to the disclosure, includes an interfacial nitride layer vertically between a base material having a first conductivity type and an emitter material with a second conductivity type.

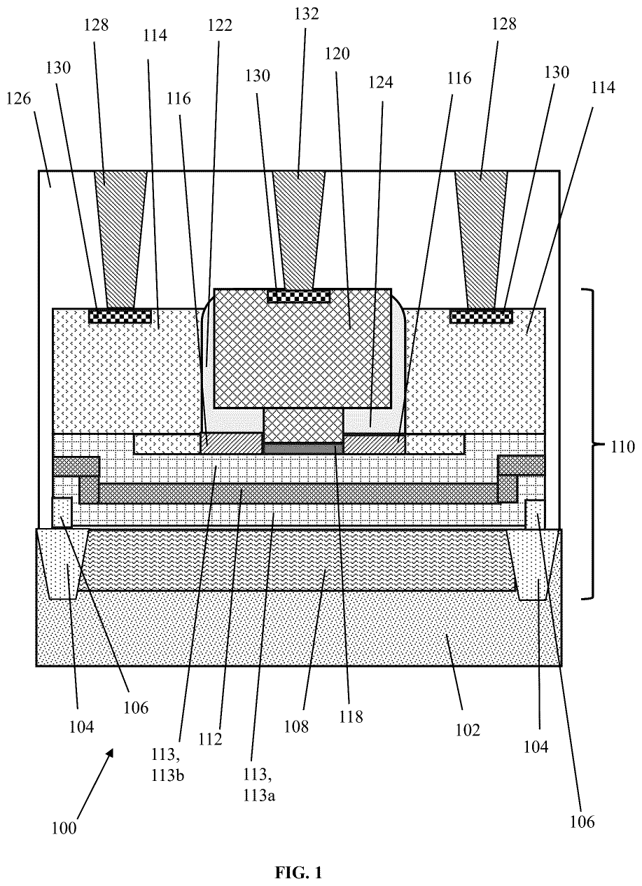

Bipolar junction transistor (BJT) structures, such as those in embodiments of the disclosure (FIGS. 1, 8, and 9), operate using multiple “P-N junctions.” The term “P-N” refers to two adjacent materials having different types of conductivity (i.e., P-type and N-type), which may be induced through dopants within the adjacent material(s). A P-N junction, when formed in a device, may operate as a diode. A diode is a two-terminal element that behaves differently from conductive or insulative materials between two points of electrical contact. Specifically, a diode provides high conductivity from one contact to the other in one voltage bias direction (i.e., the “forward” direction), but provides little to no conductivity in the opposite direction (i.e., the “reverse” direction). In the case of the P-N junction, the orientation of a diode's forward and reverse directions may be contingent on the type and magnitude of bias applied to the material composition of one or both terminals, which affects the size of the potential barrier. In the case of a junction between two semiconductor materials, the potential barrier will be formed along the interface between the two semiconductor materials. Generally, a BJT structure includes a base region vertically or horizontally between emitter and collector materials. A BJT can be either a PNP-type BJT or an NPN-type BJT. In a PNP-type BJT, the emitter and collector regions have P-type conductivity, and at least a portion of the base region has N-type conductivity. In an NPN-type BJT, the emitter and collector regions have N-type conductivity, and at least a portion of the base has P-type conductivity.

Referring to FIG. 1, structure 100 (FIGS. 1 and 8) according to the disclosure may include a bipolar transistor 110 (e.g., a vertically oriented bipolar junction transistor as discussed herein) in which an interfacial nitride layer 118 is between an intrinsic base 112 and an emitter material 120. Structure 100 (FIGS. 1 and 8) may be formed on a subcollector 102 (i.e., a doped portion of a semiconductor substrate), including, e.g., one or more monocrystalline semiconductor materials. Subcollector 102 may include but is not limited to silicon, germanium, silicon germanium, silicon carbide, or any other common integrated circuit (IC) semiconductor substrates. In the case of silicon germanium, the germanium concentration in subcollector 102 may differ from other silicon germanium-based structures described herein. A portion or entirety of subcollector 102 may be strained. Subcollector 102 may be doped (i.e., it may define a “doped well”), e.g., to enable coupling to the lower active semiconductor materials of a vertical bipolar junction transistor. Subcollector 102 may have any conceivable doping type and/or doping composition appropriate for use within and/or coupling to the collector terminal of a bipolar transistor. For instance, subcollector 102 may have the same dopant type as a collector material 108 formed thereon, e.g., P-type doping in the case of a PNP-type BJT or N-type doping in the case of an NPN-type BJT, and/or may have a higher or lower dopant concentration therein.

As shown in FIG. 1, structure 100 (FIGS. 1 and 8) may include a set of dielectric layers 104, 106. Specifically a first dielectric layer 104, and a second dielectric layer 106 thereover, on subcollector 102 for additional electrical and physical separation of bipolar transistor 110 from other components. A lower portion of first dielectric layer 104 may be horizontally adjacent to a respective side of collector material 108, and/or may horizontally surround collector material 108 outside the cross-section shown, described further herein. Although any number of dielectric layers 104, 106 may be present, two are shown as an example. In some configurations, first dielectric layer 104 on subcollector 102 may be one or more oxide-based or nitride-based insulators (e.g., silicon dioxide and/or other combinations of silicon and oxygen in different proportions), or other materials having similar properties. Second dielectric layer 106 on first dielectric layer 104 may be one or more oxide-based or nitride-based insulators (e.g., silicon nitride and/or other combinations of silicon and nitrogen in different proportions) or other materials having similar properties but other combinations are possible. In some cases, only one dielectric layer (i.e., only one of layer 104 or layer 106) may be present, and/or additional layers may be present to provide an oxide-nitride-oxide (ONO) stack or other combination of insulative materials on subcollector 102.

However embodied, dielectric layers 104, 106 may extend over subcollector 102 above the height of collector material 108 (described further herein) over subcollector 102. Dielectric layers 104, 106 may also be horizontally alongside portions of a first semiconductor film 113a (described further herein) on collector material 108. Dielectric layers 104, 106 may be formed, e.g., by deposition of desired material(s) on subcollector 102. Depending on the shape of dielectric layers 104, 106, collector material 108, when formed, may have a sloped or tapered shape, e.g., with tapered sidewalls. In cases where collector material 108 has inwardly tapered sidewalls, various materials on collector material 108 (e.g., intrinsic base 112 discussed herein) also may have tapered sidewall profiles, e.g., by selective epitaxial growth of additional material on collector material 108.

Collector material 108 may be on subcollector 102, e.g., as a single layer or multiple horizontally separated and distinct layers formed by epitaxial deposition of silicon, silicon germanium, and/or other semiconductor materials on subcollector 102. In some embodiments, collector material 108 may have a predetermined doping type, e.g., by being doped in-situ or during formation of semiconductor material(s) of subcollector 102. Collector material 108 may define an active semiconductor material of a vertical bipolar junction transistor and thus may be vertically below other terminals (i.e., intrinsic base 112, extrinsic base 114, and emitter material 120 discussed herein) of bipolar transistor 110 (FIGS. 1, 7, and 8).

Continuing with FIG. 1, Bipolar transistor 110 may include an intrinsic base 112 on collector material 108. Intrinsic base 112 may include, e.g., monocrystalline silicon germanium or any other monocrystalline semiconductor material that is doped to have a predetermined polarity. In various implementations, collector material 108, emitter material 120, and base material (including extrinsic base 114, intrinsic base 112, and semiconductor films 113) of a BJT are made of the same semiconductor material (e.g., silicon germanium). However, when at least a portion of the base material (including extrinsic base 114, intrinsic base 112, and semiconductor films 113) is made of a different semiconductor material (e.g., silicon as opposed to silicon germanium) than collector material 108 and emitter material 120, the BJT is referred to in the art as a heterojunction bipolar transistor (HBT). In the case where bipolar transistor 110 is an NPN-type transistor and subcollector 102 and collector material 108 are doped n-type, intrinsic base 112 may be doped p-type to form a P-N junction, and hence a base-to-collector interface. It is also understood that intrinsic base 112 may be doped n-type in the case where bipolar transistor 110 is a PNP-type transistor. However embodied, intrinsic base 112 may extend to a predetermined height over collector material 108.

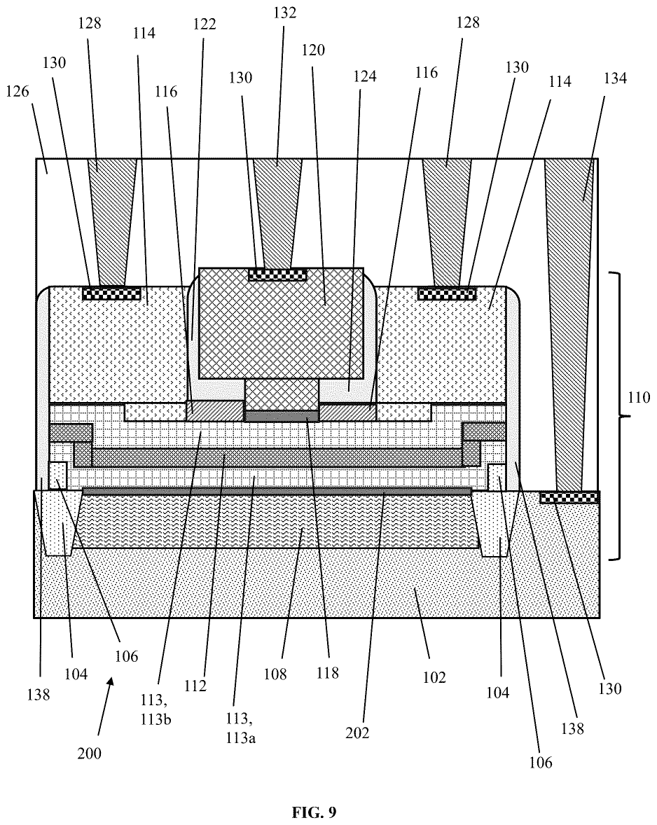

Intrinsic base 112 may be structurally and compositionally distinct from other portions of a base terminal for bipolar transistor 110 (e.g., extrinsic base 114). Intrinsic base 112 in particular may be lightly doped, or possibly undoped, whereas other base materials (e.g., extrinsic base 114 discussed herein) may be doped more highly than intrinsic base 112. Intrinsic base 112 may be formed, e.g., by depositing an initial (seed) layer of monocrystalline and/or other semiconductor materials, which may be monocrystalline silicon or silicon germanium as discussed herein, on collector material 108 or additional interfacial nitride layer 202 (shown in FIG. 9). Through selective epitaxial growth, deposition, and/or other processing, intrinsic base 112 can be formed from the initial layer to a desired height over collector material 108, first dielectric layer 104, and a second dielectric layer 106. Additional semiconductor material may be formed through selective epitaxial growth and/or similar processes to form additional semiconductor material while preserving the crystallographic orientation and/or composition of the underlying material(s).

Optionally, semiconductor films 113 (e.g., a layer of crystalline silicon and/or other semiconductor having a different composition from intrinsic base 112) may be formed adjacent to intrinsic base 112. For example, a first semiconductor film 113a may be vertically between collector material 108 and intrinsic base 112, and a second semiconductor film 113b may be vertically between intrinsic base 112 and emitter material 120. In some embodiments, semiconductor films 113 may be formed by any currently known or later developed technique to form transitional semiconductor material having varying conductivity types and/or dopant concentrations. Semiconductor films 113 may include, e.g., non-doped silicon or lightly doped silicon in various crystalline forms, e.g., single crystallographic orientation silicon, polycrystalline silicon, etc. Semiconductor films 113 may have a similar conductivity and/or doping concentration as intrinsic base 112, but may include a different semiconductor material, to function as an etch stop layer. Semiconductor films 113 in particular may allow only a portion of extrinsic base materials formed thereon to be removed and subsequently replaced with interfacial nitride layer 118 and an emitter material 120, thereby preventing any portion of intrinsic base 112 from being removed. During operation, semiconductor films 113 may have the same or similar conductivity as intrinsic base 112 and thus semiconductor films 113 may define a portion of intrinsic base 112.

Extrinsic base(s) 114 of bipolar transistor 110 may be on intrinsic base 112 (and second semiconductor film 113b of semiconductor films 113, where applicable). Extrinsic base 114 may include a polycrystalline semiconductor (e.g., polycrystalline silicon germanium) with a relatively high amount of the same doping type as (e.g., more p-type doping than) intrinsic base 112. Extrinsic base 114 may be formed, e.g., by depositing an initial (seed) layer of monocrystalline and/or other semiconductor materials on intrinsic base 112 and/or second semiconductor film 113b. Through selective epitaxial growth, deposition, and/or other processing, extrinsic base 114 can be formed from the initial layer to a desired height. The combination of extrinsic base 114, intrinsic base 112, and semiconductor films 113 may herein be referred to collectively as base material.

In some embodiments, as shown in FIG. 1, structure 100 (FIGS. 1 and 8) may include a nitride layer 116 on intrinsic base 112 (including semiconductor films 113 where applicable) and/or partially within extrinsic base 114. As shown, nitride layer 116 may be on second semiconductor film 113b of semiconductor films 113 of intrinsic base 112, e.g., by removing portions of extrinsic base 114 over second semiconductor film 113b and forming nitride layer 116 within and/or in place of the removed extrinsic base 114 material. In some embodiments, nitride layer 116 may be formed over the exposed intrinsic base 112 (including second semiconductor film 113b thereof) using any known or later developed semiconductor fabrication process(es). In some embodiments, nitride layer 116 may be formed using a thermal nitridation process. The thermal nitridation process may include heating intrinsic base 112 (including second semiconductor film 113b thereof) in a nitrogen-rich atmosphere (e.g., ammonia gas) to form nitride layer 116 on the exposed surface of intrinsic base 112 (including second semiconductor film 113b thereof). The vertical thickness of nitride layer 116 may vary depending on the application. Interfacial nitride layer 118 may then be etched from nitride layer 116 to a vertical thickness that allows emitter material 120 to electrically connect to intrinsic base 112 (including second semiconductor film 113b thereof) and may vary in vertical thickness depending on the application. In some embodiments, the vertical thickness of interfacial nitride layer 118 may be between approximately 0.1 nm and approximately 3.0 nm. The interfacial nitride layer 118 may reduce dopant diffusion from emitter material 120 to intrinsic base 112.

Emitter material 120 may be on interfacial nitride layer 118 and/or partially within extrinsic base 114. As shown, emitter material 120 may be over second semiconductor film 113b of semiconductor films 113 of intrinsic base 112, e.g., by removing portions of extrinsic base 114 over second semiconductor film 113b and forming emitter material 120 over nitride layer 116 and interfacial nitride layer 118 within and/or in place of the removed extrinsic base 114 material. Emitter material 120 may have the same doping type as subcollector 102 and collector material 108, and thus, has an opposite doping type relative to intrinsic base 112. In the case where bipolar transistor 110 is an NPN device, collector material 108 and emitter material 120 may be doped n-type to provide the two n-type active semiconductor materials, and intrinsic base 112 (including semiconductor films 113 where applicable) may be doped p-type. Emitter material 120 may include monocrystalline silicon and/or other monocrystalline semiconductor materials, including one or more materials used elsewhere in structure 100 to form subcollector 102, collector material 108, extrinsic base 114, or intrinsic base 112 (with different doping), etc.

As shown in FIG. 1, structure 100 (FIGS. 1 and 8) may include one or more spacers, e.g., a first spacer 122 and a second spacer 124, adjacent to emitter material 120 to structurally and electrically separate emitter material 120 from extrinsic base 114 and/or contacts formed thereto. First spacer 122 and second spacer 124 may include several layers having different compositions to control (e.g., increase) the electrical insulation of emitter material 120 and nearby portions of extrinsic base 114. Optionally, additional layers of first spacer 122 and/or second spacer 124 may be formed to provide a particular arrangement of insulative materials between extrinsic base 114 and emitter material 120. Other compositions and/or arrangements of spacers 122, 124 currently known or later developed also may be used. Spacers 122, 124 thus may include oxide materials, nitride materials, and/or any other insulative material discussed herein, e.g., compositions similar to first dielectric layer 104 or other insulating structures. Spacers 122, 124 may be formed, e.g., by depositing layers of spacer material such that each covers any exposed surfaces and inner sidewalls of extrinsic base 114 before other materials (e.g., emitter material 120) are formed adjacent spacers 122, 124 and on a desired portion of extrinsic base 114. In some implementations, spacers 122, 124 may include a single layer or more than two layers.

Structure 100 (FIGS. 1 and 8) may include an inter-level dielectric (ILD) layer 126 over extrinsic base 114, emitter material 120, etc. ILD layer 126 may include the same insulating material as first dielectric layer 104 or may include a different electrically insulative material for vertically separating active materials from overlying materials, e.g., various horizontally extending wires or vias. ILD layer 126 and first dielectric layer 104 nonetheless constitute different components, e.g., due to first dielectric layer 104 being vertically between subcollector 102 and the various active components of structure 100 (FIGS. 1 and 8). ILD layer 126 may be formed by deposition and/or other techniques to provide electrically insulating materials, and can then be planarized (e.g., using chemical-mechanical-polishing (CMP)), such that its upper surface remains above any active components formed on subcollector 102.

A set of base contacts 128 through ILD layer 126 may provide the vertical electrical coupling to extrinsic base 114 from overlying metal wires and/or vias. Base contacts 128, notably, do not extend to intrinsic base 112. As such, intrinsic base 112 is coupled to base contacts 128 only through extrinsic base 114. Some portions of extrinsic base 114 may be converted into a silicide layers 130 to improve conductivity between each base contact 128 and any portions of extrinsic base 114 thereunder, e.g., by providing a conductive metal such as cobalt, titanium, nickel, platinum, or similar material on the upper surface(s) of a targeted material. The conductive material(s) may be annealed while in contact with the underlying semiconductor to produce silicide layers 130 for electrically coupling semiconductor materials to any contacts formed thereon. Excess conductive material can then be removed using any now known or later developed solution, e.g., etching.

Structure 100 (FIGS. 1 and 8) also includes an emitter contact 132 to emitter material 120 and a collector contact 134 (FIGS. 8 and 9 only) to subcollector 102. Each contact 132, 134 also may be coupled to emitter material 120 or subcollector 102, respectively, through silicide layers 130 formed therein. Each contact 132, 134 also may extend through ILD layer 126, thus connecting active semiconductor material within subcollector 102 or emitter material 120 to overlying metal wires, vias, etc., above structure 100. Contacts 128, 132, 134 optionally may be formed as part of a single operation, e.g., by removing portions of ILD layer 126 to form openings, forming silicide layers 130 on semiconductor materials exposed within the openings, and filling the openings with metal to define each contact 128, 132, 134. One or more of contacts 128, 132, 134 may include refractory metal liners (not separately shown) on their sidewalls to impede or prevent electromigration degradation, shorting to other components, etc.

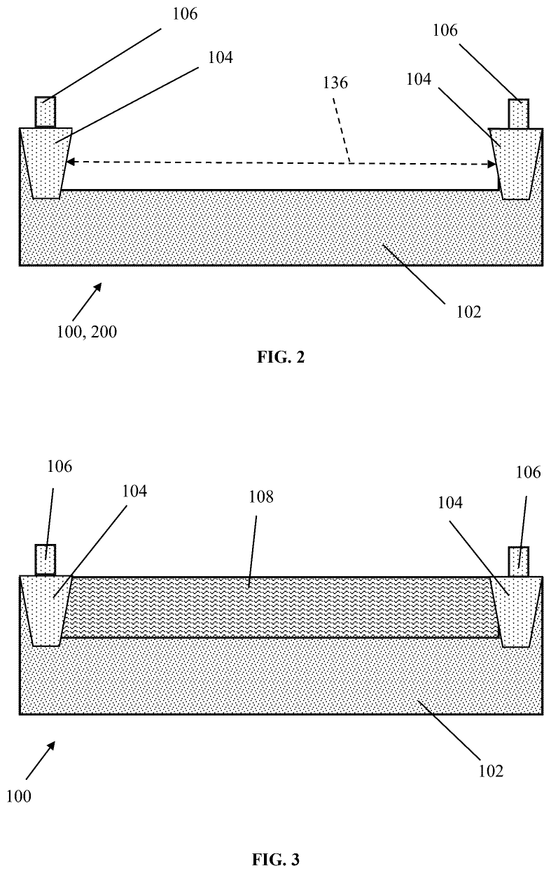

Referring to FIG. 2, methods to form structure(s) 100 (FIGS. 1, 7, and 8), 200 (FIG. 9) are also provided. Initially, only first dielectric layer 104 and second dielectric layer 106 of structure 100 may be located on subcollector 102. Subcollector 102 may be formed using any known or later developed semiconductor fabrication process(es). In some embodiments, subcollector 102 may be formed by deposition (e.g., epitaxial growth) and subsequent planarization. Any deposition described herein may include any now known or later developed techniques appropriate for the material to be deposited, including but are not limited to: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation. Any planarization described herein may include any now known or later developed techniques appropriate for making a surface planar (that is, flat and/or smooth), for example, CMP. Dielectric layers 104,106 may be formed, e.g., by deposition and subsequent etching, of any currently known or later developed dielectric material (e.g., one or more nitride-based and/or oxide-based insulators) on subcollector 102. Methods of the disclosure may include forming a trench 136 within first dielectric layer 104 and second dielectric layer 106, e.g., via one or more forms of etching. The process(es) implemented to form trench 136 may terminate at the upper surface of subcollector 102, e.g., by controlling the etch time to form trench 136 and/or by using any currently known or later developed selective etchants operable to remove first dielectric layer 104 and second dielectric layer 106 material(s) without significantly removing or otherwise affecting semiconductor materials (e.g., subcollector 102).

Turning to FIG. 3, further processing may include forming collector material 108 within trench 136 (not shown). Collector material 108 may be formed by any known or later developed semiconductor process. In some embodiments, collector material 108 may be formed by selective epitaxial growth and/or doping of semiconductor materials within trench 136. As shown, such processing may include forming collector material 108 on subcollector 102, in which collector material 108 and subcollector 102 have the same doping type but collector material 108 has a lower doping concentration. In the case of forming by epitaxial growth, collector material 108 may have sidewall shapes dependent on the shape of dielectric layers 104, 106, the manner of growth implemented and/or the crystallographic orientation of subcollector 102 thereunder.

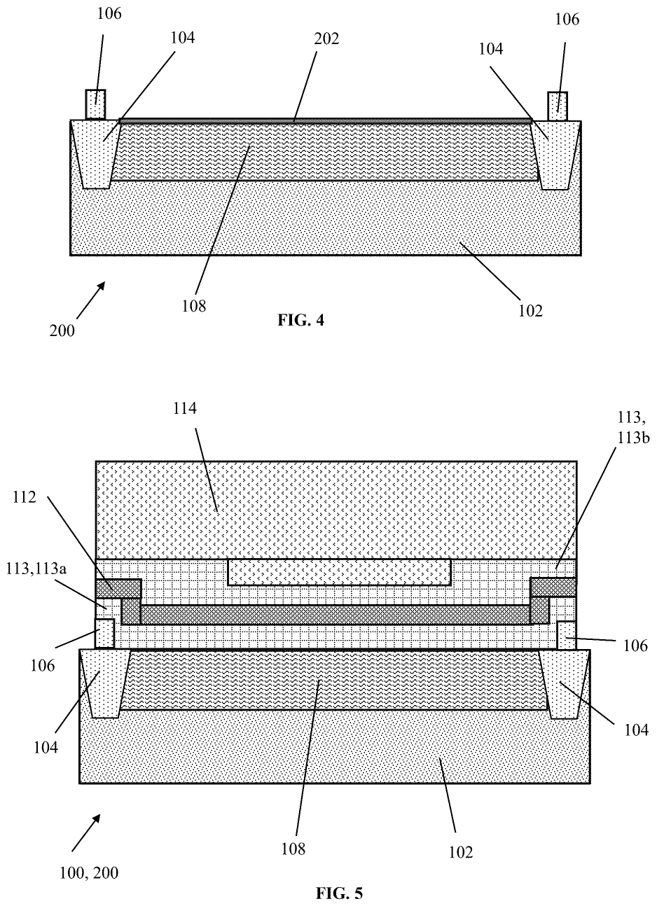

Referring to FIG. 4, which depicts a modified process flow implemented on the structure shown in FIG. 2, methods of the disclosure may include forming an additional interfacial nitride layer 202. In some embodiments additional interfacial nitride layer 202 may be formed over collector material 108 using any known or later developed semiconductor fabrication process(es). In some embodiments, additional interfacial nitride layer 202 may be formed using a thermal nitridation process. The thermal nitridation process may include heating collector material 108 in a nitrogen-rich atmosphere (e.g., ammonia gas) to form a nitride layer. The vertical thickness of the nitride layer may vary depending on the application. Once the nitride layer has been formed, a patterned mask (not shown) e.g., a nitride hard mask, may be formed on the surface of the nitride layer.

After the patterned mask is formed, one or more etching processes may be used, where there are openings in the patterned mask, to remove portions of nitride layer to form the shape of additional interfacial nitride layer 202 (as shown in FIGS. 4 and 9). Any masks described herein may be removed using any known removal process appropriate for the mask material, e.g., a wet etch for a hard nitride mask or an ashing process (oxygen dry strip process) for a soft resist-based mask. As these processes are well known, no further details are provided so the reader can focus on the salient aspects of the disclosure. Additional interfacial nitride layer 202 may be positioned so as to be between collector material 108 and intrinsic base 112 (to be formed, including first semiconductor film 113a, discussed herein). Additional interfacial nitride layer 202 may have a vertical thickness that allows collector material 108 to electrically connect to intrinsic base 112 (to be formed) and may vary in vertical thickness depending on the application. In some embodiments, the vertical thickness of additional interfacial nitride layer 202 may be between approximately 0.1 nm and approximately 3.0 nm. Additional interfacial nitride layer 202 may reduce dopant diffusion from collector material 108 to intrinsic base 112.

As shown in FIG. 5, further processing may include forming intrinsic base 112 (including semiconductor films 113 thereof), and extrinsic base 114 by selective epitaxial growth and/or doping of semiconductor materials within trench 136 (not shown). Further processing may include, e.g., forming intrinsic base 112 as a monocrystalline semiconductor material on collector material 108 and extrinsic base 114 as a monocrystalline semiconductor material over intrinsic base 112. Intrinsic base 112 and extrinsic base 114 may have an opposite doping type from collector material 108. Extrinsic base 114 may have a higher dopant concentration than intrinsic base 112, but the same conductivity type.

The forming of intrinsic base 112 may include forming semiconductor films 113 (e.g., a layer of semiconductor material, doped during growth or after growth in situ to have the same conductivity as intrinsic base 112) with a different composition and/or crystallographic orientation) on or within a portion of intrinsic base 112. The doping of semiconductor films 113 also may be achieved by thermal annealing after semiconductor films 113 are formed, in which case dopants will diffuse into semiconductor films 113 from underlying and/or overlying layers to maintain a significantly low capacitance across semiconductor film 113. In subsequent processing, semiconductor films 113 may function as a part of intrinsic base 112 but also may provide an etch stop layer to control the location and size of interfacial nitride layer 118 and emitter material 120 (FIGS. 1 and 6-9) formed thereon. The combination of extrinsic base 114, intrinsic base 112, and semiconductor films 113 may be referred to collectively as base material.

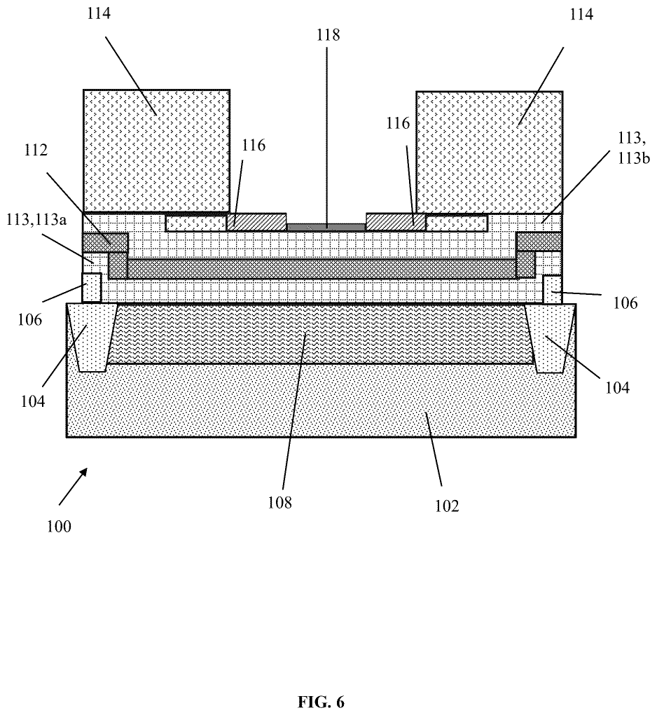

FIG. 6 depicts further processing, which may include forming a nitride layer 116 over second semiconductor film 113b. Such processing may include, e.g., forming one or more openings in extrinsic base 114 and (e.g., through etching). In cases where semiconductor films 113 are present, semiconductor films 113 may act as an etch stop layer to prevent any intrinsic base 112 beneath semiconductor films 113 from being removed inadvertently. For example, portions of extrinsic base 114 may be removed through the use of wet etching and/or other currently known or later developed selective etching materials operable to remove certain doped semiconductor materials (e.g., single crystal silicon germanium) without removing other semiconductor materials (e.g., non-crystalline silicon). In some embodiments, nitride layer 116 may be formed over the exposed second semiconductor film 113b using any known or later developed semiconductor fabrication process(es). In some embodiments, nitride layer 116 may be formed using a thermal nitridation process. The thermal nitridation process may include heating intrinsic base 112 (including second semiconductor film 113b thereof) in a nitrogen-rich atmosphere (e.g., ammonia gas) to form nitride layer 116 on the exposed surface of intrinsic base 112 (including second semiconductor film 113b thereof). The vertical thickness of nitride layer 116 may vary depending on the application.

Once nitride layer 116 has been formed a patterned mask (not shown) e.g., a nitride hard mask, may be formed on the surface of nitride layer 116. After the patterned mask is formed, one or more etching processes may be used, where there are openings in the patterned mask, to remove portions of nitride layer to form the shape of interfacial nitride layer 118 (as shown in FIG. 1 and 5-8). The patterned mask may then be removed using any known removal process appropriate for the mask material, e.g., a wet etch for a hard nitride mask. Interfacial nitride layer 118 may be positioned so as to be between a lowermost surface of emitter material 120 (to be formed) and intrinsic base 112 (including second semiconductor film 113b thereof). Interfacial nitride layer 118 may have a vertical thickness that allows emitter material 120 (to be formed) to electrically connect to intrinsic base 112 (including second semiconductor film 113b thereof) and may vary in vertical thickness depending on the application. In some embodiments, the vertical thickness of interfacial nitride layer 118 may be between approximately 0.1 nm and approximately 3.0 nm. Interfacial nitride layer 118 may reduce dopant diffusion from emitter material 120 (to be formed) to intrinsic base 112.

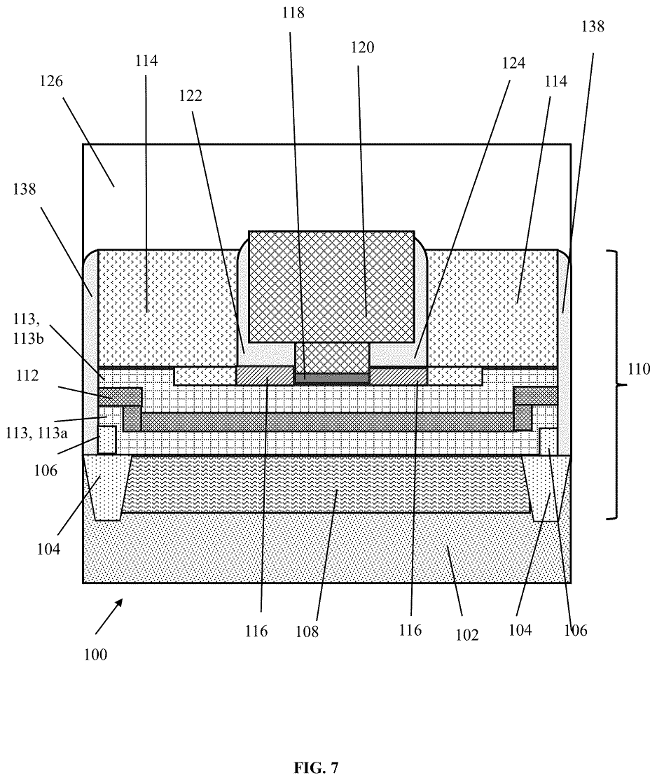

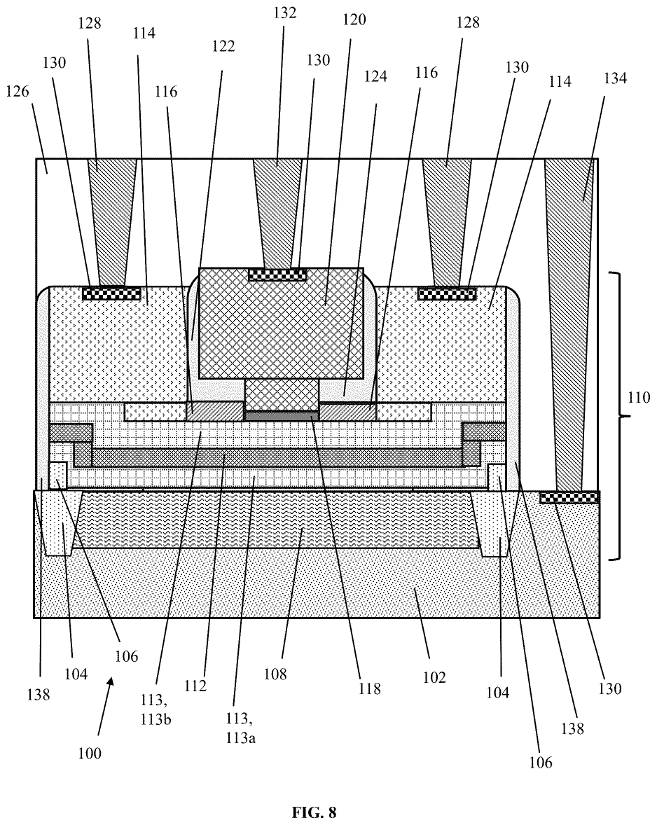

FIG. 7 depicts further processes to form structure 100 (FIGS. 1 and 8), 200 (FIG. 9) and accompanying materials. Such processing may include filling openings in extrinsic base 114 with first spacer 122 and second spacer 124 (e.g., through conformal deposition and etching). Emitter material 120 may then be formed by selective or non-selective deposition of doped semiconductor material (e.g., n-type or p-type doped semiconductor(s) such as silicon or silicon germanium) on interfacial nitride layer 118 and spacers 122, 124. Additionally, sidewall spacers 138 may be formed on first dielectric layer 104 and adjacent to intrinsic base 112 and extrinsic base 114. Sidewall spacers 138 may electrically isolate structure(s) 100, 200 from other devices. Further processing to form structure(s) 100 (FIGS. 1 and 8), 200 (FIG. 9) may include forming ILD layer 126 around bipolar transistor 110 and over subcollector 102.

FIG. 8 depicts structure 100 after forming silicide layers 130 (FIGS. 1, 8, and 9) and contacts 128, 132, 134. Silicide layers 130 may be formed on emitter material 120, extrinsic base 114 (so as to be in electrical connection with intrinsic base 112), and subcollector 102 (so as to be in electrical connection with collector material 108). Any metal silicide layer discussed herein may be formed of cobalt silicide, nickel silicide, tungsten silicide, titanium silicide, or any other suitable metal silicide material. Silicide layers 130 may be formed according to conventional processing techniques. Contacts 128, 132, 134 may be formed on respective silicide layers 130 using any known or later developed semiconductor fabrication process(es) (e.g., deposition). In one non-limiting example, contacts 128, 132, 134 may be formed by patterning a mask (not shown) over ILD layer 126, etching contact openings to the respective structures, and forming a conductor in the openings. The conductor may include a refractory metal liner and a contact metal. The refractory metal liner (not shown for ease of illustration) may include, for example, titanium nitride. Contacts 128, 132, 134 may be any now known or later developed contact metal, such as but not limited to tungsten. Contacts 128, 132, 134 may be formed on portions of emitter material 120, extrinsic base 114 (so as to be in electrical connection with intrinsic base 112), and subcollector 102 (so as to be in electrical connection with collector material 108).

FIG. 9 depicts structure 200, which includes a modified process flow as shown in FIG. 4 in which methods of the disclosure may include forming an additional interfacial nitride layer 202. As previously discussed, additional interfacial nitride layer 202 may be vertically between collector material 108 and intrinsic base 112 (including first semiconductor film 113a thereof). Additional interfacial nitride layer 202 may have a vertical thickness that allows collector material 108 to electrically connect to intrinsic base 112 and may vary in vertical thickness depending on the application. In some embodiments, the vertical thickness of additional interfacial nitride layer 202 may be between approximately 0.1 nm and approximately 3.0 nm. Additional interfacial nitride layer 202 may reduce dopant diffusion from collector material 108 to intrinsic base 112.

Embodiments of the disclosure provide various technical and commercial advantages, examples of which are discussed herein. Embodiments of the disclosure are operable to reduce dopant diffusion between the emitter material 120 and/or the collector material 108 and the intrinsic base 112 (including semiconductor films 113). Decreasing dopant diffusion may increase the performance of bipolar transistor 110 and may increase the lifespan of the device.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
an interfacial nitride layer vertically between a base material having a first conductivity type, and an emitter material with a second conductivity type.

2. The structure of claim 1, wherein the first conductivity type is P-type conductivity and the second conductivity type is N-type conductivity.

3. The structure of claim 1, wherein the structure is a heterojunction bipolar junction transistor.

4. The structure of claim 1, wherein the interfacial nitride layer is below a lowermost surface of the emitter material.

5. The structure of claim 1, wherein a vertical thickness of the interfacial nitride layer between the base material and the emitter material, is between approximately 0.1 nm and approximately 3.0 nm.

6. The structure of claim 1, further comprising an additional interfacial nitride layer vertically between the base material and a collector material below the base material, the collector material having the second conductivity type.

7. A vertical bipolar junction transistor comprising:
a base material on a collector material, wherein the base material has a first conductivity type and the collector material has a second conductivity type opposite the first conductivity type, and the base material includes:
an intrinsic base on the collector material, and
an extrinsic base coupled to the intrinsic base, wherein the extrinsic base has a higher dopant concentration than the intrinsic base;
an interfacial nitride layer on the intrinsic base of the base material; and
an emitter material on the interfacial nitride layer and having the second conductivity type, wherein the interfacial nitride layer is vertically interposed between the base material and the emitter material.

8. The vertical bipolar junction transistor of claim 7, wherein the first conductivity type is P-type conductivity and the second conductivity type is N-type conductivity.

9. The vertical bipolar junction transistor of claim 7, wherein the vertical bipolar transistor is a heterojunction bipolar transistor.

10. The vertical bipolar junction transistor of claim 7, wherein the interfacial nitride layer is below a lowermost surface of the emitter material.

11. The vertical bipolar junction transistor of claim 7, wherein a vertical thickness of the interfacial nitride layer between the base material and the emitter material, is between approximately 0.1 nm and approximately 3.0 nm.

12. The vertical bipolar junction transistor of claim 7, further comprising an additional interfacial nitride layer vertically between the intrinsic base and the collector material.

13. A method comprising:
forming a base material having a first conductivity type;
forming an interfacial nitride layer on the base material; and
forming an emitter material on the interfacial nitride layer, the emitter material having a second conductivity type.

14. The method of claim 13, wherein the first conductivity type is P-type conductivity and the second conductivity type is N-type conductivity.

15. The method of claim 13, further comprising forming a collector material having the second conductivity type, below the base material,
wherein the base material, the interfacial nitride layer, the emitter material, and the collector material define a heterojunction bipolar transistor.

16. The method of claim 15, wherein the interfacial nitride layer is formed below a lowermost surface of the emitter material.

17. The method of claim 15, wherein a vertical thickness of the interfacial nitride layer, between the base material and the emitter material, is between approximately 0.1 nm and approximately 3.0 nm.

18. The method of claim 15, further comprising forming an additional interfacial nitride layer between the base material and a collector material, the collector material with a second conductivity type.
